(19) United States
(12) Patent Application Publication
(10) Pub. No.: US 2006/0267608 A1
(43) Pub. Date: Nov. 30, 2006

(54) ADAPTIVE TEST METER PROBE SYSTEM AND METHOD OF OPERATION

(76) Inventor: Robert Faust, Highlands Ranch, CO (US)

Correspondence Address: HULSEY IP INTELLECTUAL PROPERTY LAWYERS, P.C., 1250 S. CAPITAL OF TEXAS HIGHWAY, BUILDING THREE, SUITE 610, AUSTIN, TX, 78746, US

(21) Appl. No.: 11/383,950

(22) Filed: May 17, 2006

Related U.S. Application Data
(60) Provisional application No. 60/682,292, filed on May 18, 2005.

(51) Int. Cl. G01R 31/02

(52) U.S. Cl. 324/754

(57) ABSTRACT

A Novel probe tip adapted to connect to an existing probe tip, the novel probe tip includes a probe, wherein the probe includes a first end and a second end with the second end of the probe adapted to securely and electrically attached to an existing probe tip which is connected to a testing device and wherein the first end of the probe is capable of probing an electronic or electrical circuit.

This application claims the benefit of U.S. Provisional Application Serial No. 60/682,292, filed May 18, 2005 under 35 U.S.C. 119(e) and is incorporated by reference as if fully set forth herein.

### FIELD OF THE INVENTION

This disclosure pertains to electrical and electronic test systems, and more specifically to system for providing probes connecting between a test meter or oscilloscope and an electrical or electronic connection. Even more specifically, the disclosed subject matter provides an adaptive test meter probe system and method of operation.

### BACKGROUND OF THE INVENTION

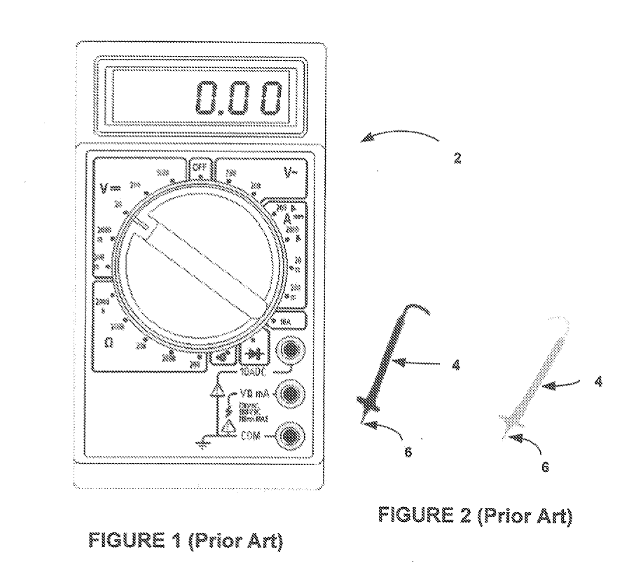

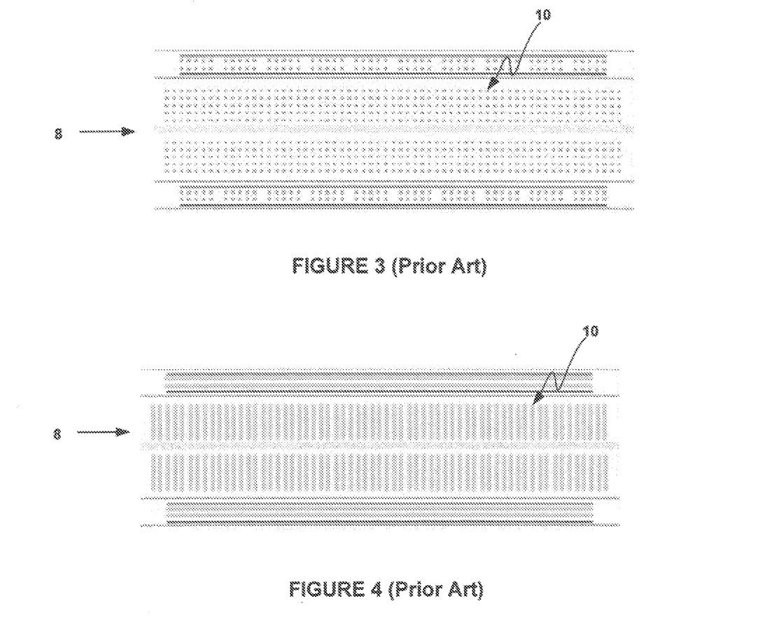

Instruments, such as multimeters 2, (See Prior art FIG. 1) and oscilloscopes are sold with a standard probe configuration that is usually unsatisfactory for a number of reasons. For example, known multimeter probes 4, Prior art FIG. 2, are frequently sold with a 2 mm diameter pins 6. The 2 mm pins protrude and generally are sharpened to a point. These probes 4 do not work well with a solderless breadboard 8 (See Prior Art FIG. 3), motherboard or integrated circuits. For instance, on a solderless breadboard 8, contact occurs when the probe 4, is pushed down into the breadboard receiving slot 10. The 2 mm pin 6 of a common multimeter probe 4 is usually too large to fit into the solderless breadboard receiving slots 10. As seen in the Prior Art FIG. 4, wherein the wiring or component has been placed to form an electronic circuit, it can be difficult to probe regions of the circuit due to the spacing constraints of the board and the size of the multimeter 2 probe tips 4.

On the other hand, frequently there is the need to grip connectors, for example, using an alligator grip, in order to connect the multimeter to the contacts. Therefore, in order to accomplish this task the existing or original probe tips 4 are removed and an alternate set of probe tips 4 are connected to the multimeter 2, so as to provide this functionality.

If additional functionality is required, this results in the use of multiple probe tips 4 in various configurations to perform a multitude of different tasks. This typically requires the user to have multiple sets of probe tips 4 and the resulting tangling of the probe tip 4 connecting cables. As is often the case, many multimeters and oscilloscopes have hard wired probe tips 4 and cannot be easily interchanged without some disassembly of a portion of the device being utilized. This is can be time consuming and very inefficient

Furthermore, a multimeter probe 4 may need to connect with a specific mating connector, i.e., a male or female mating connector. Oftentimes, there is the need to specifically probe the female or male connector. This need is generally not addressable with a 2 mm probe tip 6.

With all of the different potential applications for a multimeter, a profound failing of many such devices is a clear lack of flexibility and general usefulness of the associated meter probe configuration. Accordingly, there is a need for an improved probe system for multimeters and oscilloscopes to serve a wide variety of electrical and electronic testing and measuring applications that attaches to the existing or original probe tips 6.

The need for different probe tips holds true also for different oscilloscope applications. Oscilloscopes may include a small gripper jaw attachment mechanism that serves to attach to different connectors. However, for solderless breadboards and a host of other configurations, the common probe tip 4 for an oscillator does not work well in these applications. The applications and attendant functionality may include larger alligator clips, micro clips or other types of connectors. That is, with the wide variety of applications for oscilloscopes, there is not a similar wide variety of probe tips 4 capable of such uses.

The prior art is deficient in that it does not provide for the adapting of the existing or original probe tips 4 to perform various testing procedures.

Thus, there is a need for a method and system that allows oscilloscopes and other testing devices to probe a wide variety of contact or conductive test situations that attach to the existing or original probe tips 4.

### SUMMARY OF THE INVENTION

The present invention has been made in view of the above circumstances and has as an aspect a novel probe tip connection.

A further aspect of the present invention is a novel probes tip connection and probe tip assembly.

Additional aspects and advantages of the invention will be set forth in part in the description which follows, and in part will be obvious from the description, or may be learned by practice of the invention. The aspects and advantages of the invention will be realized and attained by means of the elements and combinations particularly pointed out in the appended claims.

To achieve these and other advantages and in accordance with the purpose of the present invention, as embodied and broadly described, the present invention can be characterized according to one aspect the invention comprises a novel probe tip adapted to connect to an existing probe tip, the novel probe tip comprising a probe, wherein the probe includes a first end and a second end; wherein the second end of the probe is capable of being securely and electrically attached to an existing probe tip which is connected to a testing device; and wherein the first end of the probe is capable of probing an electronic or electrical circuit.

The present invention can be further characterized according to another aspect of the invention as a set of probe tips for attaching to an existing testing device probe lead, the set of probes comprising a set of probes, wherein the set of probes adapts the existing probe leads to perform the functions of gripping and probing at least one of a blade, post, rail, terminal or large wire; gripping and probing at least one of small electronic component, small wire or integrated circuit pin; piercing and probing an insulated conductor without stripping away the conductor's insulation; brushing an area of an integrated circuit in performing a continuity check; measuring a battery supplied current while driving a circuit without disrupting circuit connections; and magnetically attaching to a circuit while probing the circuit.)

It is to be understood that both the foregoing general description and the following detailed description are exemplary and explanatory only and are not restrictive of the invention, as claimed.

The accompanying drawings, which are incorporated in and constitute a part of this specification, illustrate several embodiments of the invention and together with the description, serve to explain the principles of the invention.

FIG. 1 is a prior art schematic diagram of a multimeter;

FIG. 2 is a prior art diagram of a breadboard socket;

FIG. 3 is a prior art diagram of a breadboard socket with component wiring performed;

FIG. 4 is a prior art diagram of 2 mm needle type probe tips.

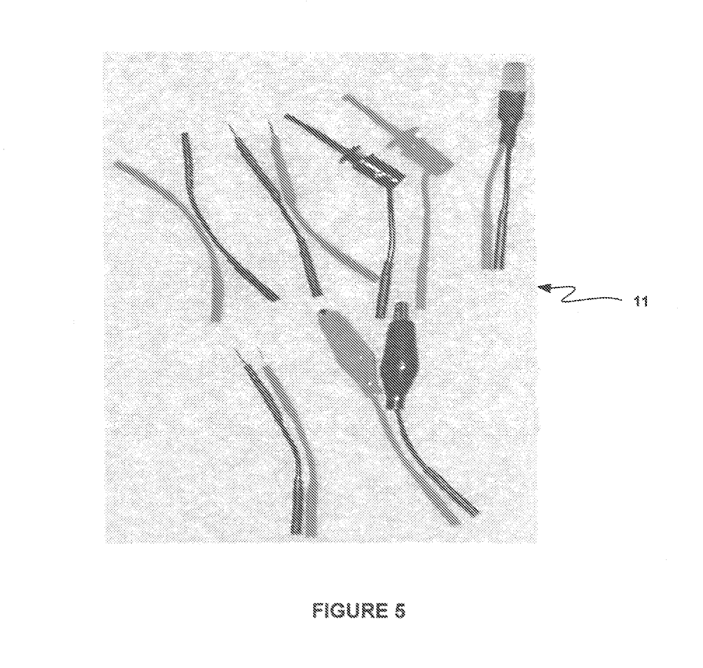

FIG. 5 is a diagram depicting several embodiments of the present invention;

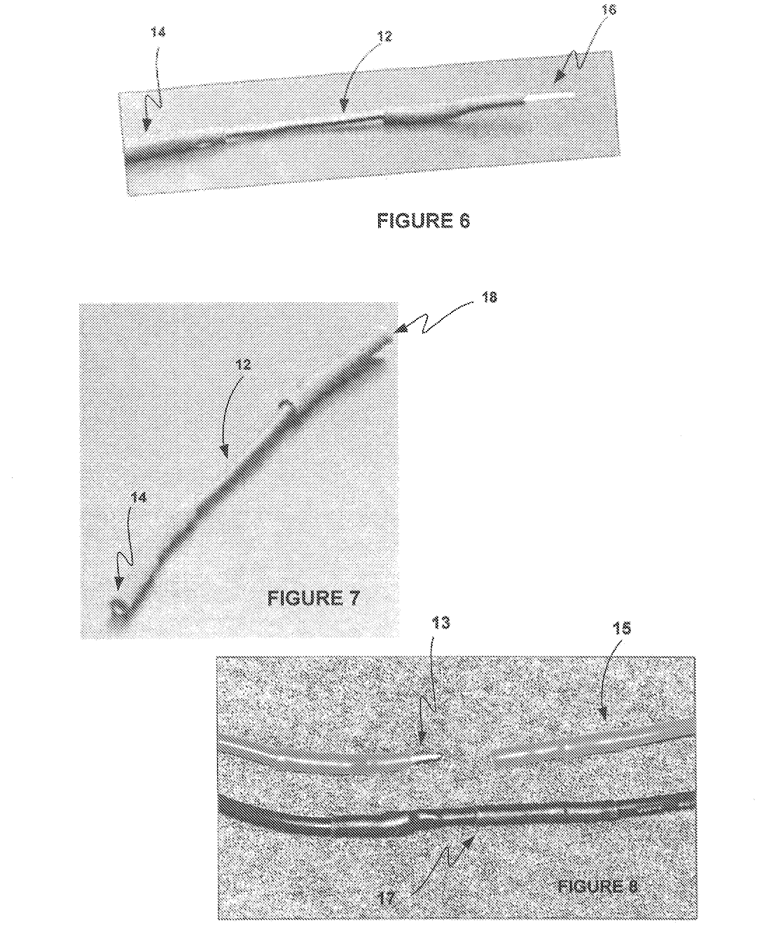

FIG. 6 depicts a diagram of a novel probe tip of one embodiment of the present invention;

FIG. 7 depicts a diagram of a female-female adapter of an embodiment of the present invention;

FIG. 8 depicts a diagram of a alternate embodiment of the present invention;

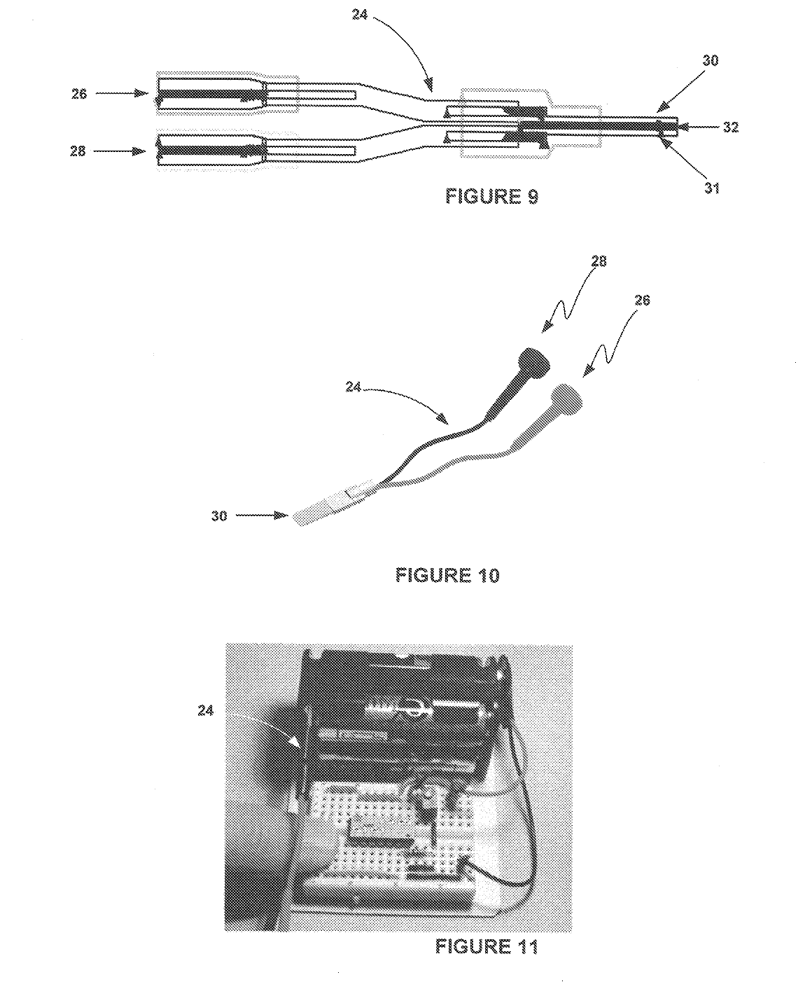

FIG. 9 depicts a schematic diagram of an embodiment of the present invention;

FIG. 10 depicts a prototype of an embodiment of the present invention;

FIG. 11 depicts a diagram of a dual blade current probe embodiment of the present invention;

FIG. 12 depicts a formation of a novel ferrule of the present invention;

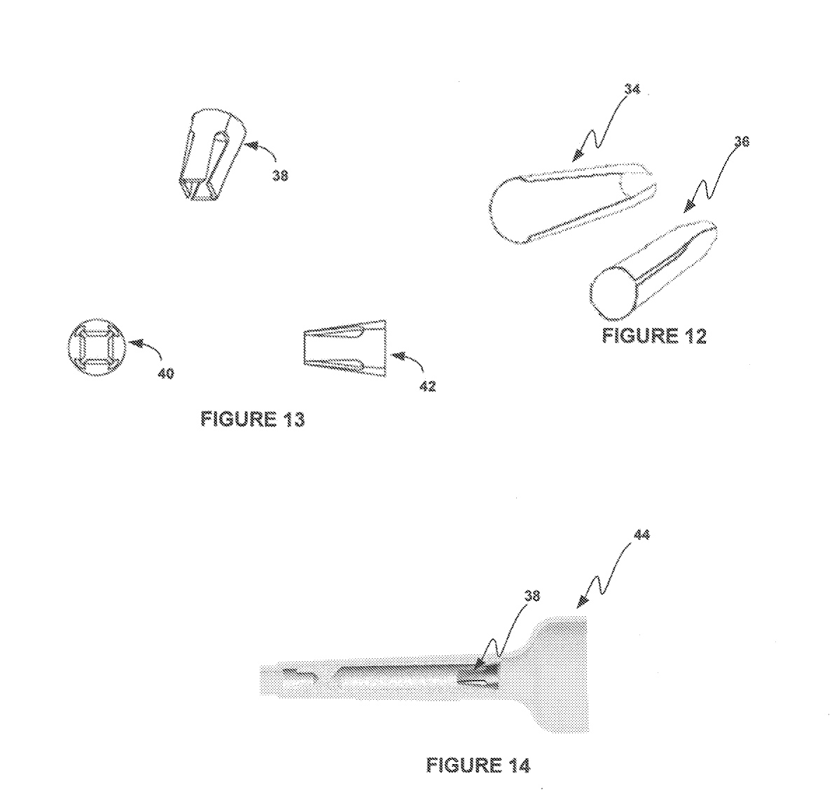

FIG. 13 depicts a further formation of the novel ferrule of the present invention;

FIG. 14 depicts a cut way view of the ferrule prototype of the present invention;

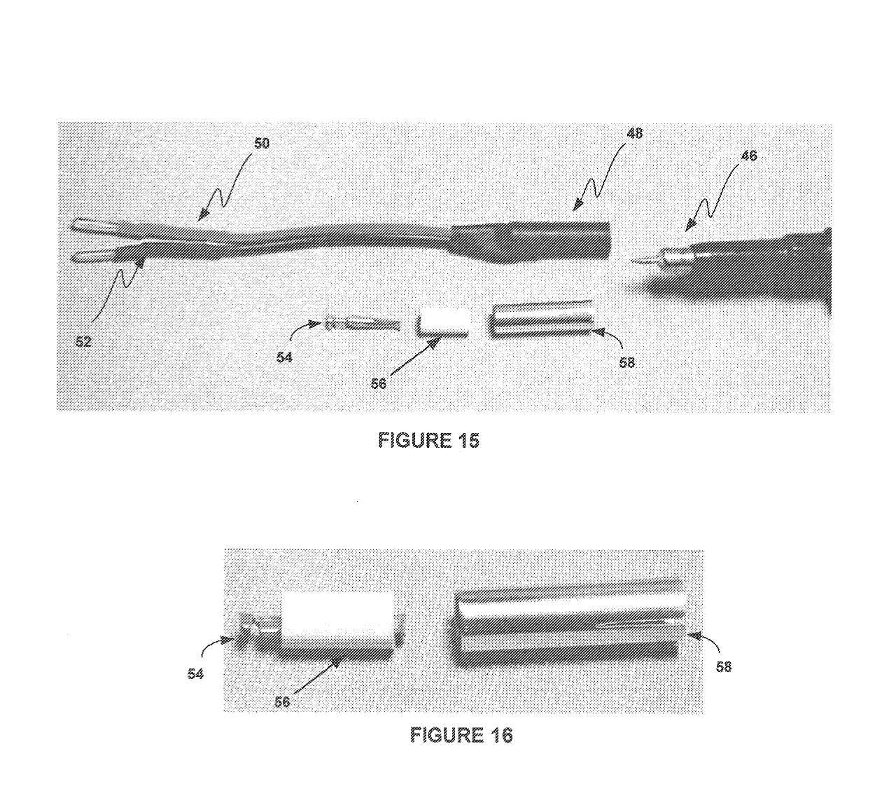

FIG. 15 depicts the fabrication of an adapter of an embodiment of the present invention for an oscilloscope;

FIG. 16 depicts the fabrication of an adapter of an embodiment of the present invention for an oscilloscope;

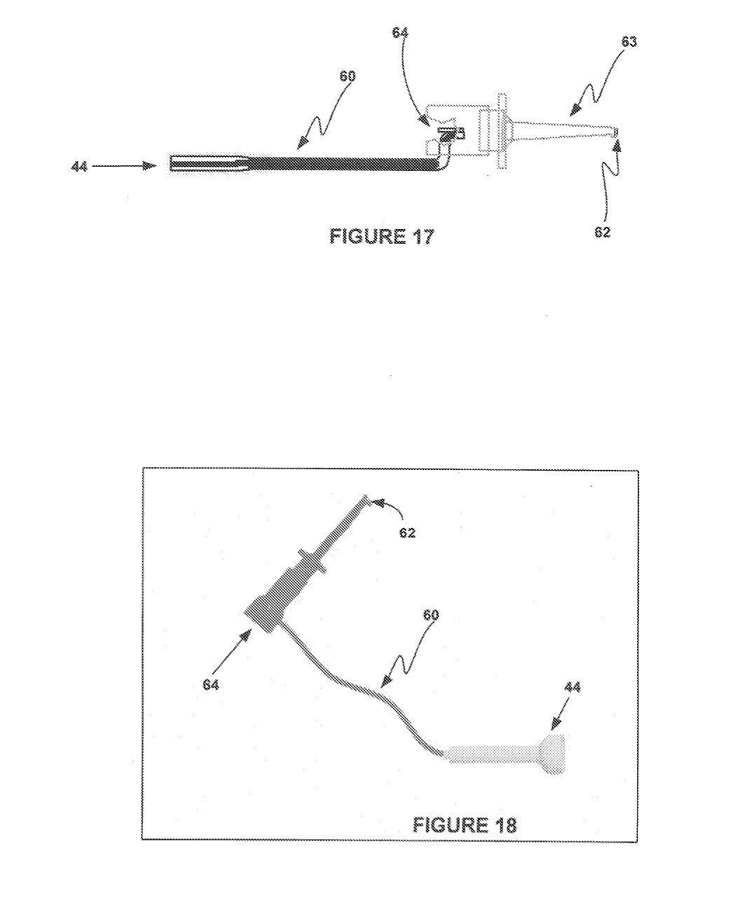

FIG. 17 depicts a schematic diagram of a micro test clip probe of the present invention;

FIG. 18 depicts a prototype of the micro test clip probe of the present invention;

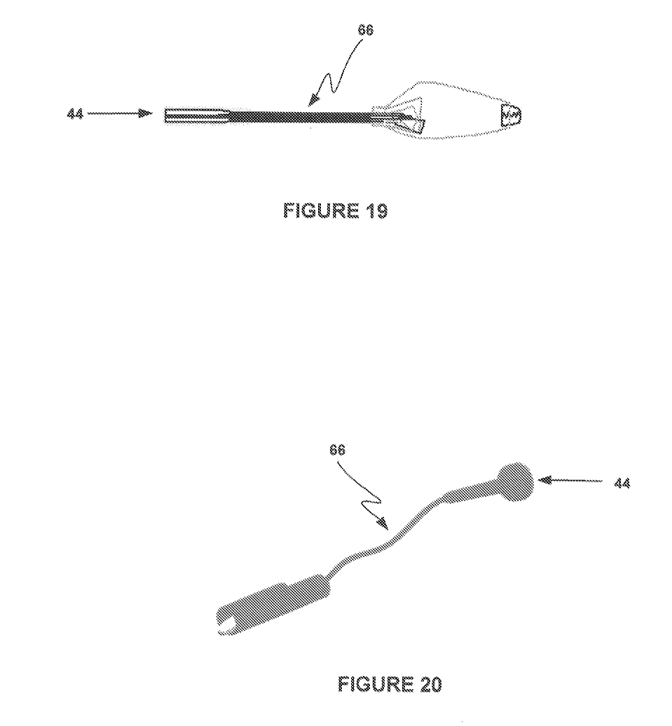

FIG. 19 depicts a schematic diagram of an alligator clip of an embodiment of the present invention;

FIG. 20 depicts a prototype of the alligator clip of FIG. 19;

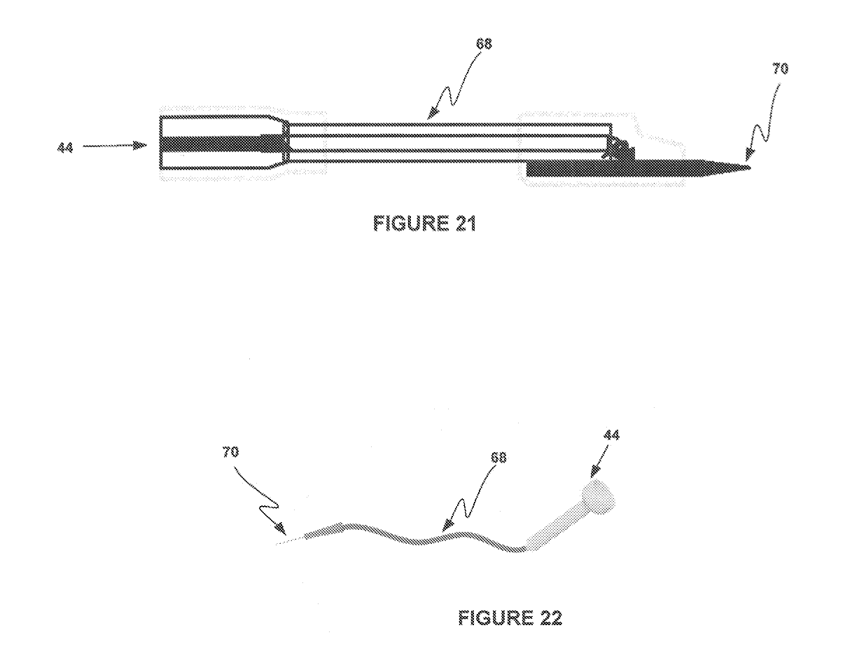

FIG. 21 depicts a schematic diagram of a needle probe of an embodiment of the present invention;

FIG. 22 depicts a prototype of the needle probe of FIG. 21;

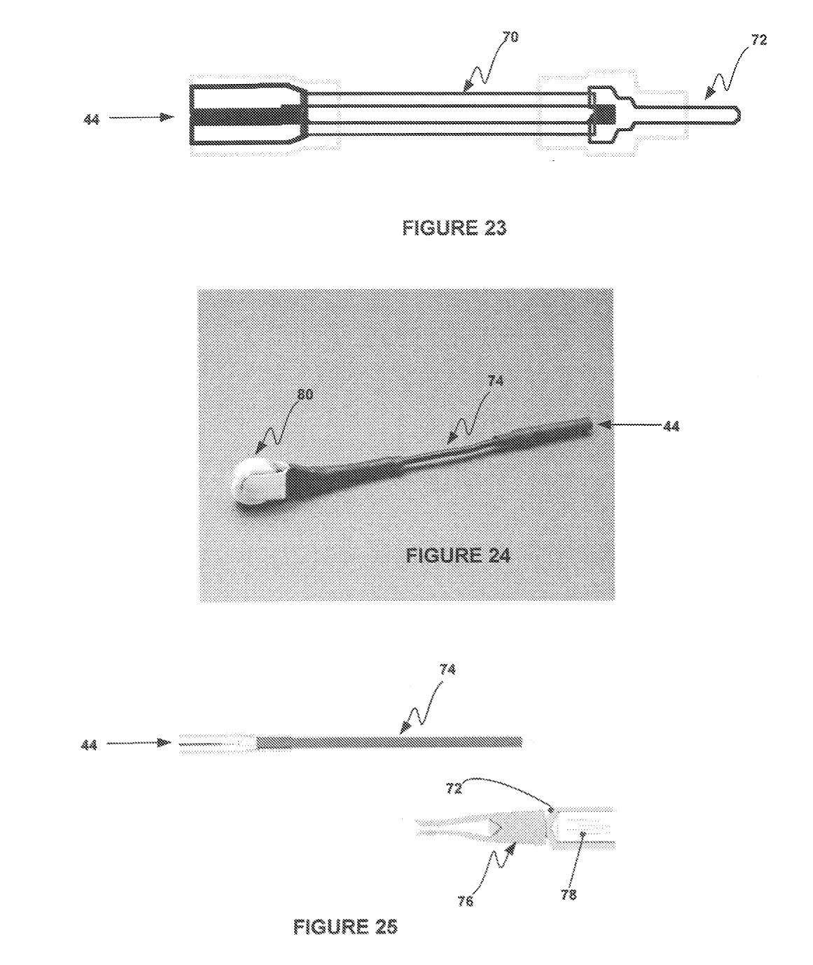

FIG. 23 depicts a schematic diagram of a solder less breadboard probe of an embodiment of the present invention;

FIG. 24 depicts a prototype of the solderless of breadboard probe of FIG. 23;

FIG. 25 depicts an exploded view of a magtip probe of an embodiment of the present invention;

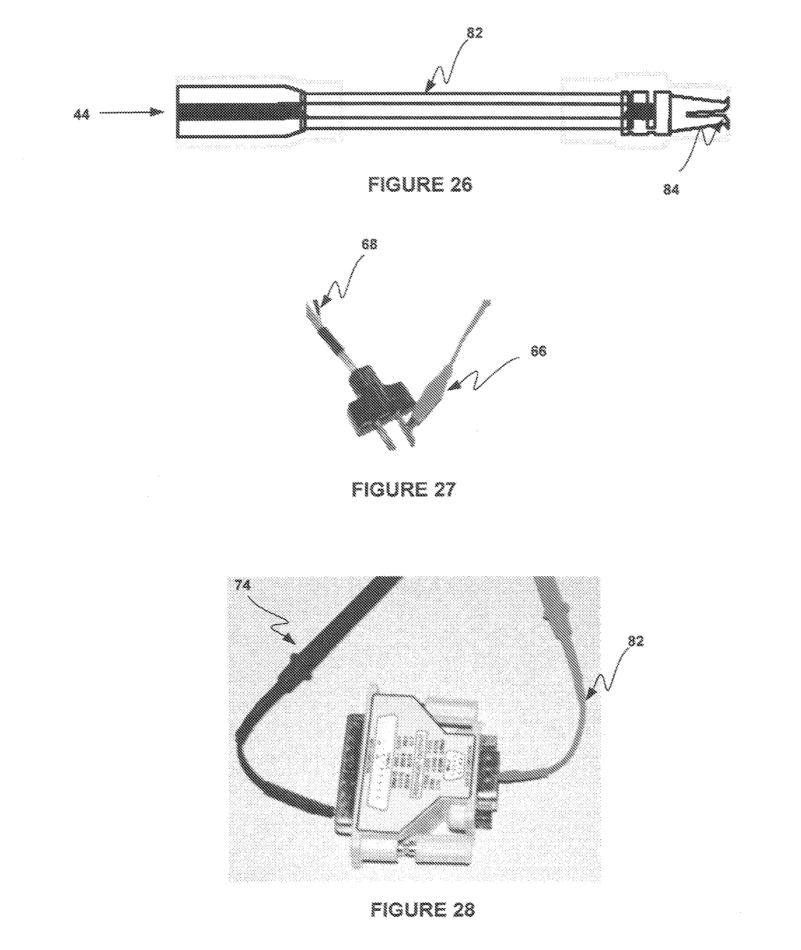

FIG. 26 depicts a schematic diagram of a connector pin probe of an embodiment of the present invention;

FIG. 27 depicts and example of the alligator probe and the needle probe embodiments of the present invention in operation;

FIG. 28 depicts an example of the connector pin socket and breadboard pin embodiments of the present invention in operation;

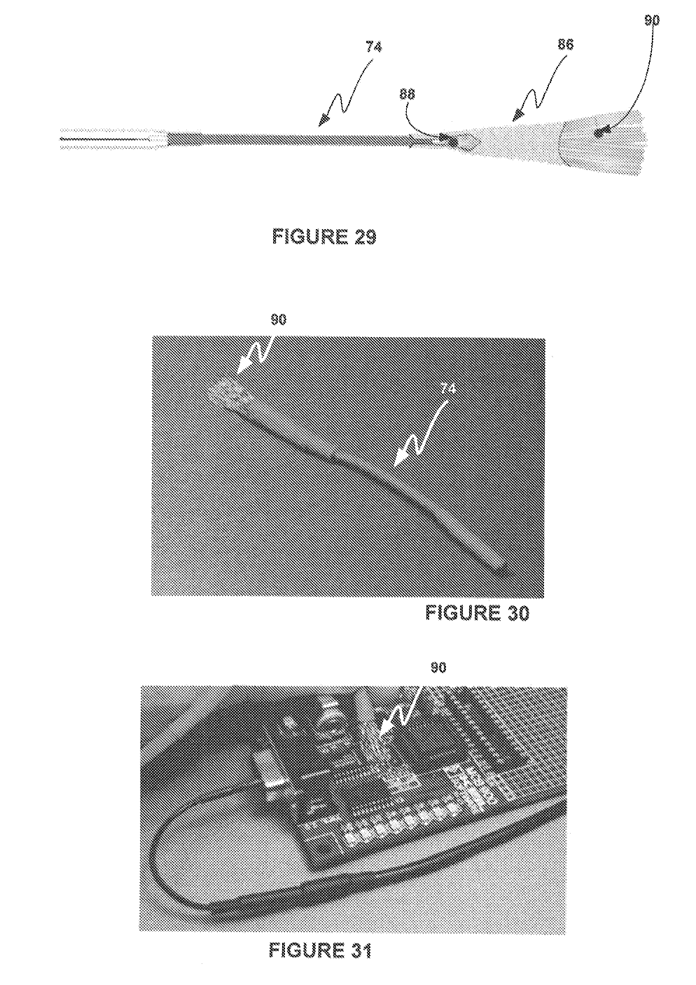

FIG. 29 depicts a schematic diagram of a brass brush probe of an embodiment of the present invention;

FIG. 30 depicts a prototype of the brass brush probe of FIG. 29;

FIG. 31 depicts an example of a the brass brush probe embodiment of the present invention in operation;

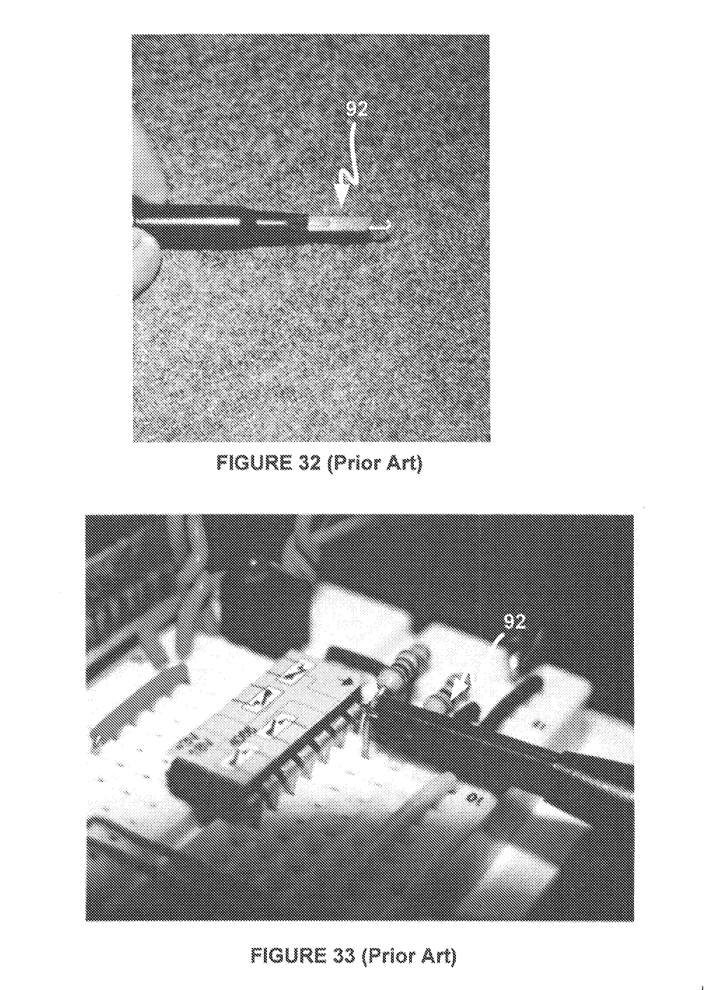

FIG. 32 depicts a view of a prior art spring hook probe; and

FIG. 33 depicts a view of a prior art spring hook probe in operation.

### DESCRIPTION OF ILLUSTRATIVE EMBODIMENTS

Reference will now be made in detail to the present embodiments of the invention, and examples of which are) illustrated in the accompanying drawings. Wherever possible, the same reference numbers will be used throughout the drawings to refer to the same or like parts (elements).

In accordance with the invention, the present invention includes a novel probe tip adapted to connect to an existing probe tip, the novel probe tip comprising a probe, wherein the probe includes a first end and a second end and wherein the second end of the probe is capable of being securely and electrically attached to an existing probe tip which is connected to a testing device. Additionally, the first end of the probe is capable of probing an electronic or electrical circuit.

As embodied herein, an aspect of the present invention includes a set of probe tips for attaching to an existing testing device probe lead, the set of probes comprising: a set of probe tips for attaching to an existing testing device probe lead, the set of probes comprising: a set of probes, wherein the set of probes adapts the existing probe leads to perform the function of: gripping and probing at least one of a blade, post, rail, terminal or large wire; gripping and probing at least one of a small electronic component, small wire or integrated circuit pin; piercing and probing an insulated conductor without stripping away the conductor'insulation; brushing an area of a integrated circuit in performing a continuity check; measuring a batter supplied current while driving a circuit without disrupting circuit connections; and magnetically attaching to a circuit while probing the circuit

FIG. 5 shows several embodiments of the present invention. FIG. 6 depicts probe tip 12 of one embodiment of the present invention that is capable of being placed securely on probe tip 6 of FIG. 2. In this embodiment end 14 is attached to probe tip 6 thereby creating a secure and electrical connection to probe tip 6, which is in turn connected to multimeter 2. In this embodiment, probe tip 12 is flexible and resilient and is capable of being twisted or bent into myriad shapes to aide in the probing of a breadboard 8 or other electronic circuitry. The connection is secured by friction grip of a ferrule (not shown) that will be discussed in detail later.

FIG. 7 depicts an alternate embodiment of the present invention of probe tip 18, wherein the probe tip includes two female ends 20 and 22. The female-female adapter 18 is typically utilized for connecting a meter probe to a pin such as those found in connector plugs. This is virtually impossible without an adapter having the configuration and properties of probe tip 18, as depicted in FIG. 7.

Furthermore, in this embodiment the probe tip 18 can be utilized to further extend the existing or original probe tip 4. Probe tips 12 and 18 typically are approximately 2 inches in length and are less than 20% of the weight of probe tip 4. The size and weight of probe tips 12 and 18 is often critical especially when utilized in an environment where the probe tip has to be connected to a portion of the circuit while other regions of the circuit are being explored.

The flexible and resilient leads of the embodiment of the present invention allows for the connection to remain intact while the probing operation continues and frees the user from having to hold that connection in place. The prior art probe tips 4 generally are too heavy and rigid to perform this function adequately as they often become dislodged due to the weight of the probe tip 4 and the users inability to place the probe tip 4 in a secure and convenient position to facility the probing of the circuit.

FIG 8 depicts an alternate embodiment of the present invention. The leads 13 and 15 represent the probe connection in a disconnected configuration and a connected configuration 17. The probe connections 13, 15 and 17 depicted in FIG. 8 represent the alteration of leads such as those employed on conventional multimeters 2. This embodiment of the present invention provides for the shortening of long meter leads so as to be convenient for bench work type applications. A long probe lead, for instance, is cut to make the desired shorter lead 17 (connected configuration). A 2 mm pin is attached to the end of the short lead 13 and when joined with the female portion of the probe lead 15 results in the probe connection 17. Any probe tip disclosed in the present invention or any prior art probe tip, can then just be simply slipped onto the 2 mm pin just as was done with the conventional long lead probe tip end by employing aspects of the present invention. The unused portion of the lead can be fitted with a standard ferrule attached so that rather than be discarded, the portion of the lead can be Utilized in the creation of a subsequent different size probe lead for a future application.

FIG. 9 depicts a schematic diagram of an alternate embodiment of the present invention. FIG. 10 depicts a prototype of the schematic diagram of FIG. 9. The dual blade current probe 24 consists of two thin metal blades 30 and 31 placed flat side by flat side with a thin insulating film 32 separating the flat surfaces 30 and 31 (as shown in FIG. 9). The dual blade current probe 24 is inserted for example, between a battery and its mating or spring terminal.

In so doing, the battery current is diverted from its normal path, which would have been into its connecting terminal, and rather is forced to flow into the lead attached to the blade contacting the battery, out through the blade leads 26 or 28, the ferrule and on through the instrument lead plugged into the ferrule. The current then returns from the instrument, goes through the other blade and into the circuit. In this manner, the dual blade current probe measures the battery supplied current as it drives the circuit without any circuit connections being disrupted.

FIG. 11 depicts the dual blade current probe in operation. The very convenient and simple insertion of the dual bladed current probe 24 does not disrupt the operation of the battery powered circuit, but rather, it forces the circuit current through the testing device so that it can be measured and monitored.

FIGS. 12 and 13 depict the formation of 34 ferrule that receives the 2 mm pins of the probe tip 4. The ferrule is made out of a beryllium metal, or any other metal suitable for this purpose, which is pliable, resilient and highly conductive. A sheet of beryllium is cut so that it forms a parallelogram and when folded (36) forms a cylindrical structure. As shown in FIG. 13, the cylindrical structure 36 is further honed such that multiple flanges are formed (see reference number 38). An end view of the ferrule 40 displays the final configuration of the ferrule after the milling process is completed. A side view of the ferrule 42 depicts the tapering configuration that facilitates the mating of the probe tip 4 with the probe tips of the present invention.

As will be appreciated by those of ordinary skill in the art, the flanges act as a spring to securely and electrically secure the probe tip 4 when mated with the novel probe tips of the present invention. FIG. 14 depicts a prototype probe tip end, wherein the ferrule 38 is disposed a distance from the insulated receiving end 44 of the novel probe tip.

FIGS. 15 and 16 depict fabrication of an adapter that slips onto oscilloscope probes so they can receive the novel probe tips of the present invention. A probe adapter 47, comprising leads 50 and 52 having a 2 mm (although other size leads with pin size greater or lesser that 2 mm may be employed with the present invention and not depart from the teachings of the present) pins to receive the novel probe tips of the present invention as well as those in the prior art. As seen in FIG. 15, the tips are extended from the insulated female adapter 48 adapted to slip onto an oscilloscope probe 46 and make contact with the coaxial center signal tip 54, the shield barrel 56 and to extend those connections to leads 50 and 52 respectively.

FIG. 16 depicts an enlarged view of the coaxial center signal tip ferrule 54, insulating sleeve 56 and large ferrule 58. The small ferrule 54 is designed to make electrical contact with the scope probes signal tip 46. The oscilloscope 46 tip fits inside ferrule 58 and is held in alignment by the white insulating sleeve 56. Ferrule 54 and sleeve 56 are held in alignment by the large outer ferrule 58. The large ferrule 58 is designed to slip onto the scope probes shield barrel, make electrical contact with it and grip it snugly while at the same time the small inner ferrule has slipped onto and made electrical contact with the signal tip. Slots cut into the large ferrule 58 are for the purpose of creating flexure of the ferrule so that it grips the probe barrel snugly (as describe with reference to FIGS. 12 and 13). The red 50 and black 52 leads are electrically attached to the small 54 and large ferrules 58 respectively.

FIG. 17 depicts a schematic diagram of a micro test clip probe tip 60 of an embodiment of the present invention. FIG. 18 depicts a prototype of the schematic diagram of FIG. 17. The micro test clip 60 is adapted to grip small elements like the leads on small components, small wires or integrated circuit pins. A tip 62 extends from the insulated housing 63 of micro test clip 60 when the spring load actuator 64 is depressed. The tip 62 can then be utilized to attach onto a small component, wire or integrated circuit pin. The ferrule 38 is enclosed in the insulated housing of the receiving end 44 and mates with the probe tip 4, oscilloscope probe tip 46 or other electronic testing equipment.

FIG. 19 depicts a schematic diagram of an alligator clip 66 of an embodiment of the present invention. FIG. 20 depicts a prototype of the alligator clip 66 of the present invention. The alligator clip is adapted to be used to grip larger elements like blades, post, rails, terminals, large wires and similar type electronic structures in the probing process. It provides the user with a secure and efficient attachment to the element under consideration while the user probes the device, as shown in FIG. 27

FIG. 21 depicts a schematic diagram of a needle probe 68 of an embodiment of the present invention. FIG. 22 depicts a prototype of the schematic diagram of FIG. 21. The needle probe 68 is adapted to pierce insulation or similar structures so that readings can be taken without damaging the insulation by stripping in the insulation. The needle probe 68 is also capable of probing tiny pins and other very small structure or area of an integrated circuit, chip etc. An example of an application of the needle probe 68 being utilized in conjunction with the alligator probe 66 can be seen in FIG. 27. A person of ordinary skill in the art will appreciate the myriad uses the needle probe 68 can be employed and still fall within the teachings of the present invention.

FIG. 23 depicts a schematic diagram of a solderless breadboard probe 70 of an embodiment of the present invention. Solderless breadboard probe 70 tip 72 is adapted such that tip 72 is easily inserted into any solderless breadboard hole for probing.

FIG. 24 depicts an exploded schematic view of a magtip probe 72 of an embodiment of the present invention. FIG. 25 depicts a prototype of the magtip 72. The magtip 72 is adapted to be utilized in the situations where it is desirable to attach the probe to the circuit and free up the users hands while probing, but there is no structure available for attachment with a conventional probe set.

For example, when testing a battery the magtip 72 will be attracted to the positive or negative terminal and attach itself to the battery once in close enough proximity. The magtip 72 attaches to one of the novel probe tips 74 in the manner as described above. Magtip 72 is comprised of a brass yoke 76 and a rare earth magnet 78. Generally, the rare earth magnet 78 with dimensions of ⅜×⅛ inch will be sufficient for most circumstances. Magtip head 80 comprises the yoke 76 and rare earth magnet 78.

FIG. 26 depicts a schematic diagram of a connector pin socket 82 of an embodiment of the present invention. The connector pin socket 82 is adapted to be slipped onto a male connector pin. Connections to female connector sockets can be made with a breadboard pin 72, which is inserted into a female connector socket. This configuration facilitates a multimeter 2 to measure continuity through either male or female connectors. The connector pin socket 82 can utilized any time a connector pin is to be probed. FIG. 28 depicts an example of the connector pin socket 82 and breadboard pin 72 in operation.

FIG. 29 depicts a schematic diagram of a brass brush probe 86 of an embodiment of the present invention. FIG. 30 depicts a prototype of the brass brush probe 86. The brass brush probe 86 is adapted to be utilized when sweeping an area for continuity. This is advantageous in that instead of probing each point separately, an area can be probed simultaneously. The brush probe 86 is comprised of a brass collar 88 and brass bristles 90. FIG. 31 depicts an example of a real world application of the brass brush probe 86 for continuity checking an electronic circuit.

FIG. 32 depicts a prior art spring hook probe 92, which slips onto oscilloscope probe 46. As shown in FIG. 33, the prior art probe is heavy and cumbersome and quite often can damage the circuit if the user is not very careful. Generally the user must use a hand to support it and not allow it to rest on the circuit. The flexible wire between novel the novel probe tip and ferrule (as shown in FIGS. 5 and 6) eliminates this deficiency and, therefore, allows for attachment to the circuit with minimal risk of damage.

A QuicTip probe (not shown) is a probe tip adapted to be utilized when instrumentation cannot be positioned close enough so that the instruments test leads will reach the desired circuitry connection points that are to be measured or monitored. More often than not, in those cases the solution is a haphazard affair of wires extended in combination with more wires containing connecting clips and bare metal hastily wrapped with tape

The main component of the QuicTip is a 2 mm pin bent in shape. The tip is used in the following way:

(1) A length of wire is selected that conveniently reaches from the instrument to the desired test circuitry called the extension wire.

(2) An insulating boot, a component of the QuicTip, is designed to completely cover the curved part of the J-shaped pin and the bare extension wire connected to it.

(3) A generous amount of the extension wire's end is stripped of insulation and the bare wire is simply wrapped around the curved part of the J shape pin. This provides a secure connection and most conveniently, without the need for soldering.

(4) When the insulating boot is positioned up and over the tip with its wrapped extension wire, all of the bare metal is safely covered and the extension wire now has its end finished with a standard 2 mm pin that can accept any tip disclose by the embodiments of the present invention.

(5) The same steps are performed on the other end of the extension wire.

(6) To connect the extension wires QuicTip 2 mm pin to the 2 mm pin on an instrument lead, a male-to-female gender changer is utilized. The male-to-female gender changer consists of a wire with ferrules on each end, and the female-to-male changer consists of a wire with 2 mm pins on each end.

While the invention herein disclosed has been described by the specific embodiments and applications thereof, numerous modifications and variations could be made thereto by those skilled in the art without departing from the scope of the invention set forth in the claims.

While various embodiments of the present embodiment have been described above, it should be understood that they have been presented by way of example only, and not limitation. It will be understood by those skilled in the art that various changes in form and details may be made therein without departing from the spirit and scope of the invention. Thus, the breadth and scope of the present embodiment should not be limited by any of the above-described exemplary embodiments, but should be defined only in accordance with the following claims and their equivalents.

I claim:

1. A novel probe tip adapted to connect to an existing probe tip, the novel probe tip comprising:
a probe, wherein the probe includes a first end and a second end;
wherein the second end of the probe is capable of being securely and electrically attached to an existing probe tip which is connected to a testing device; and
wherein the first end of the probe is capable of probing an electronic or electrical circuit.

2. The novel probe tip of claim 1, wherein the second end of the probe is capable of electrically and securely attaching to an approximately 2 mm existing probe tip.

3. The novel probe tip of claim 2, wherein the second end of the probe tip further comprises a pliable metal interface for securely and electrically receiving an existing probe tip.

4. The novel probe tip of claim 3, wherein the second end of the probe tip comprised of a pliable metal has a cylindrical ferrule configuration including a receiving end and for receiving the existing probe tip and a securing end further comprised of multiple flanges acting as a spring to receive and release the existing probe tip when inserted into the second end of the probe tip.

5. The novel probe tip of claim 4, wherein the metal interface of the second end of the probe tip is comprised of beryllium.

6. The novel probe tip of claim 1, wherein the probe tip is at least one of an alligator clip probe, a dual blade current probe, a connector pin socket probe, a solderless breadboard pin probe, a spring hook probe, a micro test clip probe, a needle probe and a brass brush probe.

7. The novel probe tip of claim 6, wherein the second end of the probe tip comprised of a pliable metal has a cylindrical ferrule configuration including a receiving end for receiving the existing probe tip and a securing end further comprised of multiple flanges acting as a spring to receive and release the existing probe tip when inserted into the second end of the probe tip.

8. The novel probe tip of claim 7, wherein the metal interface of the second end of the probe tip is comprised of beryllium.

9. The novel probe tip of claim 6, wherein the second end of the probe is capable of electrically and securely attached to an approximately 2 mm existing probe tip.

10. The novel probe tip of claim 9, wherein the second end of the probe tip comprised of a pliable metal has a cylindrical ferrule configuration including a receiving end for receiving the existing probe tip and a securing end further comprised of multiple flanges acting as a spring to receive and release the existing probe tip when inserted into the second end of the probe tip.

11. The novel probe tip of claim 10, wherein the metal interface of the second end of the probe tip is comprised of beryllium.

12. A set of probe tips for attaching to an existing testing device probe lead, the set of probes comprising:
a set of probes, wherein the set of probes adapts the existing probe leads to perform the functions of:
gripping and probing at least one of a blade, post rail, terminal or large wire;
gripping and probing at least one of a small electronic component, small wire or integrated circuit pin;
piercing and probing an insulated conductor without stripping away the conductor's insulation;
brushing an area of a integrated circuit in performing a continuity check;
measuring a battery supplied current while driving a circuit without disrupting circuit connections; and
magnetically attaching to a circuit while probing the circuit.
